(19) United States
(12) Patent Application Publication
(10) Pub. No.: US 2012/0212250 A1
(43) Pub. Date: Aug. 23, 2012

(54) Semiconductor element testing system having air filter

(75) Inventor: Pi Hui Tai, Hsinchu (TW)

(73) Assignee: King Yuan Electronics Co., Ltd., Hsinchu (TW)

(21) Appl. No.: 13/067,977

(22) Filed: Jul. 13, 2011

(30) Foreign Application Priority Data
Feb. 18, 2011 (TW) 100203036

(51) Int. Cl. G01R 31/26

(52) U.S. Cl. 324/762.01

(57) ABSTRACT

A semiconductor element testing system having an air filter includes a testing apparatus, a first hollow frame, a fan assembly, a second hollow frame, and an air filter. The testing apparatus includes a housing having an opening. The first hollow frame is arranged on the housing and includes a flange, a bottom surface, and a side portion, wherein a plurality of hooks are fixedly arranged on the side portion. The fan assembly is fixed on the first hollow frame such that a forced airflow can be supplied toward inside of the housing. The second hollow frame includes an outer side portion fixedly arranged with a plurality of loop fasteners corresponding to the plural hooks. The air filter covers on the opening of the housing. Thereby, floating particles of the testing system can be reduced so as to lower the possibility of contamination for chips.

### BACKGROUND OF THE INVENTION

1. Field of the Invention

The present invention relates to a semiconductor element testing system, and more particularly, to a semiconductor element testing system having an air filter.

2. Description of Related Art

Normally semiconductor elements are necessary to be tested by testing facilities so as to test and verify the function of the semiconductor elements. Then based on the test results, the semiconductor elements are screened and classified such that those being evaluated as good are selected and bad are eliminated. However, environmental air quality, during the test, significantly affects the test results of chips. Therefore, maintaining the testing facilities in an environment of good air quality is an essential requirement for testing semiconductor elements.

Referring to FIG. 1, a front view illustrating a conventional semiconductor element testing system, the testing system 90 is arranged in a clean environment, for example a so-called “clean room.” The testing system 90 itself is not equipped with any air filters. Semiconductor elements are disposed in a testing area 91 for being tested. Because the semiconductor elements are comparatively sensitive to particles floating in the air, higher degree of testing cleanness is required, for example Complementary metal-oxide-semiconductor elements (CMOS elements). However, since the cleanness in the testing area 91 fails to reach the requirement completely, the environment in the testing system 90 becomes worse easily. This will adversely affect testing yield rate of the semiconductor elements.

Therefore, it is understood that even if the conventional semiconductor element testing system 90 is arranged in the so-called clean room, there are still plenty of particles in the air of the environment, making the degree of cleanness fail to reach to the requirement. As such, the conventional art is undesirable, and there is still room for improvement.

In view of the above, “a semiconductor element testing system having an air filter” originated from innovative concept of the present invention is developed and accomplished, after persistent research and experiments, so as to solve the problems given above.

### SUMMARY OF THE INVENTION

A primary object of the present invention is to provide a semiconductor element testing system having an air filter characterized by using the air filter to filter, with positive pressure, the air introduced into a testing apparatus, and into a testing area, so as to reduce floating particles in the testing area, and to maintain satisfactory cleanness in the testing area. This will lower the possibility of contamination for semiconductor elements so as to enhance testing yield rate.

A secondary object of the present invention is to provide a semiconductor element testing system having an air filter, so that the air filter can be assembled to the testing apparatus easily and that time and manpower be saved.

To achieve the object, the testing system comprises a testing apparatus, a first hollow frame, a fan assemble, a second hollow frame, and an air filter. The testing apparatus includes a housing having an opening. The first hollow frame is fixedly arranged on the housing of the testing apparatus and located around the opening. The first hollow frame includes a flange, a bottom surface, and a side portion, wherein a plurality of hooks are fixedly arranged on the side portion. The fan assembly is fixed on the flange of the first hollow frame such that a forced airflow can be supplied toward inside of the housing. The second hollow frame includes an inner bottom surface and an outer side portion, wherein the outer side portion is fixedly arranged with a plurality of loop fasteners corresponding to the plural hooks of the first hollow frame. The air filter is interposed between the bottom surface of the first hollow frame and the inner bottom surface of the second hollow frame, and covers on the opening of the housing.

Further, according to the present invention, the housing may be provided, at its sides, with a plurality of slits or through holes acting as vents of the testing apparatus for flowing air in the testing area.

According to the present invention, the air filter may relate to a high efficiency particulate air filter (HEPA filter), or other equivalent air filters.

The second hollow frame may have a L-shaped cross-section such that the whole second hollow frame can be formed as a trough, and that the air filter can be disposed on the inner bottom surface of the second hollow frame without the possibility of falling.

According to the present invention, when the plural loop fasteners of the second hollow frame and the plural hooks of the first hollow frame are correspondingly engaged with one another, the air filter can be pressed against by the bottom surface of the first hollow frame and the inner bottom surface of the second hollow frame without the possibility of sliding up and down.

Further, according to the present invention, the fan assembly may be fixed on the first hollow frame by a plurality of fastening screws or other equivalents. The first hollow frame, the fan assembly, the second hollow frame, and the air filter can be assembled together so as to form a unitary fan-filter assembly which can be installed on the housing of the testing apparatus conveniently.

Still further, according to the present invention, the opening can be provided at the top, or one side, of the housing. A through hole is provided on the housing, opposite to the opening at the side of the housing, for introducing airflow. In addition, an exhaust fan can be arranged at the through hole for drawing airflow and introducing the same out of the testing apparatus. To avoid causing a turbulent flow and contaminating cleanness of the environment of the testing apparatus, the exhaust fan can be provided to introduce the drawn airflow to the ground.

Other objects, advantages, and novel features of the present invention will become more apparent from the following detailed descriptions when taken in conjunction with the accompanying drawings.

### BRIEF DESCRIPTION OF THE DRAWINGS

FIG. 1 is a front view illustrating a conventional semiconductor element testing system;

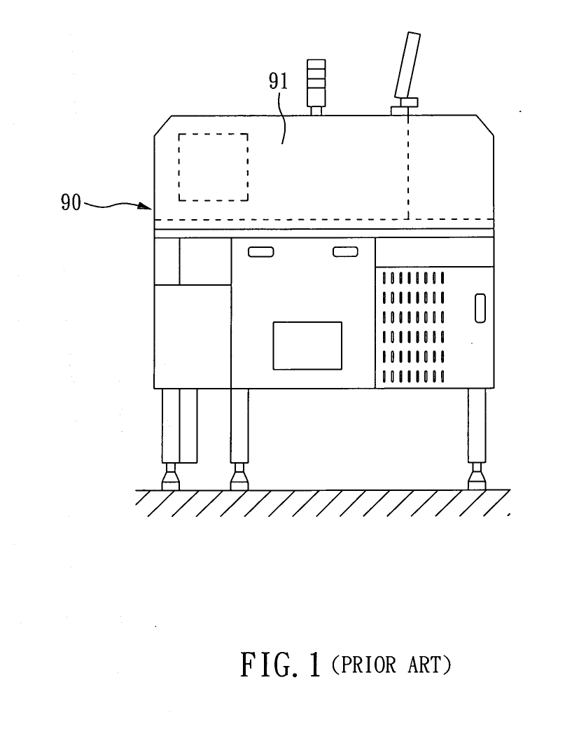

FIG. 2 is a front view illustrating a semiconductor element testing system according to a first embodiment of the present invention;

FIG. 3 is an exploded view illustrating an air filter according to the first embodiment of the present invention;

FIG. 4 is a perspective view illustrating the air filter according to the first embodiment of the present invention;

FIG. 5 is a partial enlargement of part of the air filter shown in FIG. 4; and

FIG. 6 is a front view illustrating a semiconductor element testing system according to a second embodiment of the present invention.

### DETAILED DESCRIPTION OF THE PREFERRED EMBODIMENTS

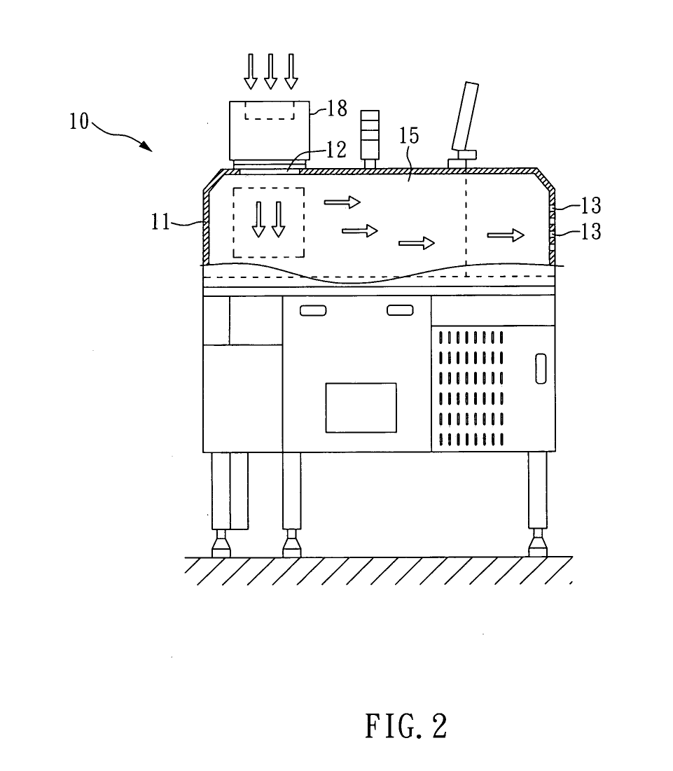

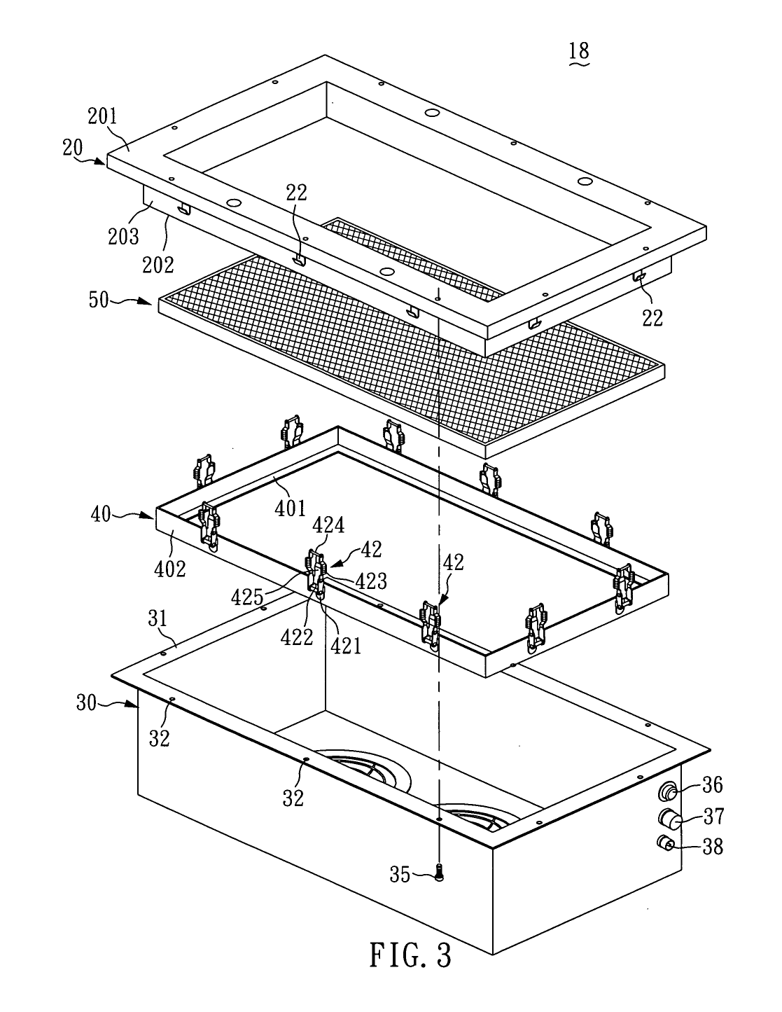

Referring to FIG. 2, a front view illustrating a semiconductor element testing system according to a first embodiment of the present invention, and to FIG. 3, an exploded view illustrating an air filter according to the first embodiment of the present invention, the testing system comprises a testing apparatus 10 and a fan-filter assembly 18.

As shown in FIG. 2, the testing apparatus 10 includes a housing 11 having an opening 12. In the first embodiment, the housing 11 is provided, at its top, with the opening 12; whereas, at its sides, with a plurality of slits 13 acting as vents for flowing air in a testing area 15. Further, the fan-filter assembly 18 is fixed on the top of the housing 11 of the testing apparatus 10 and covers on the opening 12.

As shown in FIG. 3, the fan-filter assembly 18 includes a first hollow frame 20, a fan assembly 30, a second hollow frame 40, and an air filter 50. The first hollow frame 20 includes a flange 201, a bottom surface 202, and a side portion 203, wherein a plurality of hooks 22 are fixedly arranged on the side portion 203. The fan assembly 30 is fixed on the flange 201 of the first hollow frame 20 by a plurality of fastening screws 35 passing through a plurality of through holes 32 on a flange 31 such that a forced airflow can be supplied toward inside of the housing 11 of the testing apparatus 10.

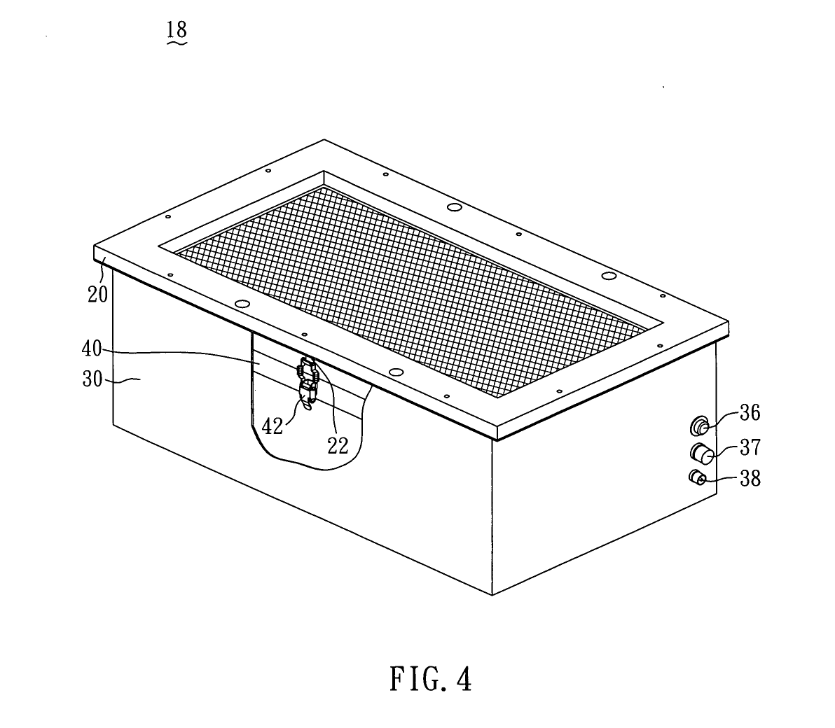

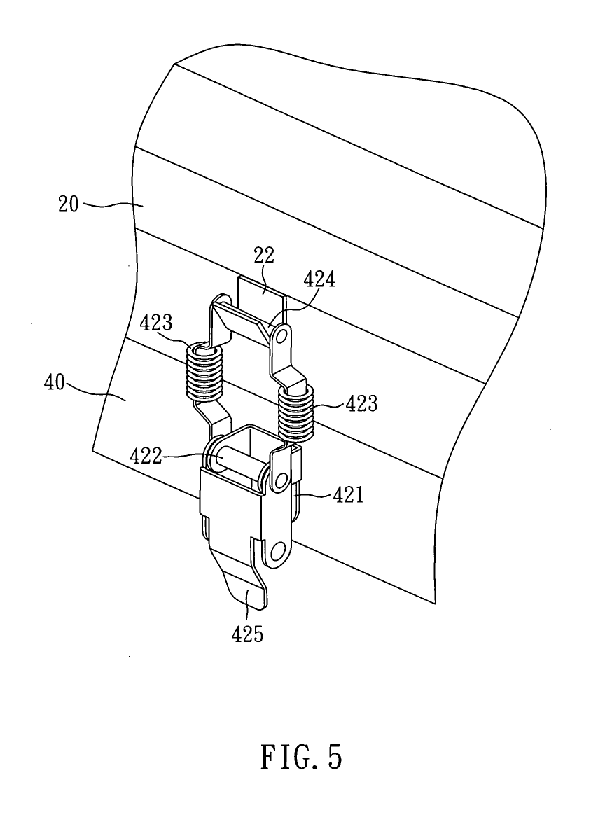

In the present embodiment, the second hollow frame 40 includes an inner bottom surface 401 and an outer side portion 402, wherein the outer side portion 402 is fixedly arranged with a plurality of loop fasteners 42 corresponding to the plural hooks 22 of the first hollow frame 20. Each loop fastener 42 consists of a seat 421, an axle 422, two spring arms 423, a fastening rod 424, and an operating piece 425. The seat 421 is fixed on the outer side portion 402, and that the two spring arms 423 are connected with each other and pivot, together with the fastening rod 424, at the axle 422. By using the operating piece 425, the loop fastener 42 and the hook 22 can be engaged with each other easily. As shown in FIG. 5, a partial enlargement of part of the air filter shown in FIG. 4, the loop fastener 42 and the hook 22 are engaged with each other such that the fastening rod 424 engages with the hook 22.

The air filter 50 is interposed between the bottom surface 202 of the first hollow frame 20 and the inner bottom surface 401 of the second hollow frame 40. In the present embodiment, the air filter 50 relates to a high efficiency particulate air filter (HEPA filter).

Further, as shown in FIG. 3, the second hollow frame 40 has a L-shaped cross-section such that the air filter 50 can be disposed on the inner bottom surface 401 of the second hollow frame 40 without the possibility of falling.

In the present embodiment, when the plural loop fasteners 42 of the second hollow frame 40 and the plural hooks 22 of the first hollow frame 20 are correspondingly engaged with one another, the air filter 50 is pressed against by the bottom surface 202 of the first hollow frame 20 and the inner bottom surface 401 of the second hollow frame 40 without the possibility of sliding up and down.

Now referring to FIG. 4, a perspective view illustrating the air filter 50 according to the first embodiment of the present invention, and to FIG. 5, a partial enlargement of part of the air filter 50, and also to FIG. 2, the first hollow frame 20, the fan assembly 30, the second hollow frame 40, and the air filter 50 are assembled together so as to form a unitary fan-filter assembly 18 which can be installed on the housing 11 of the testing apparatus 10 conveniently. This will save time and manpower. The fan assembly 30 is fixed with a starting switch 36 so as to manually control ON/OFF thereof. A fuse 37 is provided for protecting circuits of the fan assembly 30 so as to avoid too much current flow that might damage components of the fan assembly 30. A power terminal 38 serves as an entrance of an outside power supply. The outside power supply of the fan assembly 30 can be arranged independently, or arranged together with the power supply of the testing apparatus 10.

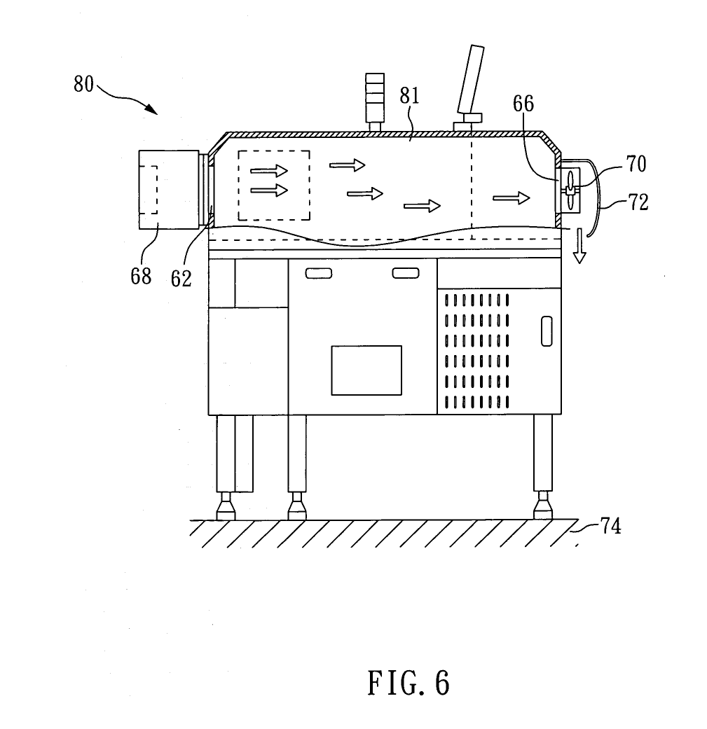

Further referring to FIG. 6, a front view illustrating a semiconductor element testing system according to a second embodiment of the present invention, the present embodiment differs from the first embodiment in that a testing apparatus 80 is provided with an opening 62 at one side of a housing 81 such that a fan-filter assembly 68 is fixed to the side of the housing 81 of the testing apparatus 80. A through hole 66, opposite to the opening 62, is provided on the housing 81, wherein an exhaust fan 70 is arranged at the through hole 66 for drawing airflow and introducing the same out of the testing apparatus 80. In addition, to avoid causing a turbulent flow when the airflow is drawn out of the testing apparatus 80 and contaminating cleanness of the environment outside of the testing apparatus 80, the exhaust fan 70 is provided with a shield 72 so as to introduce the drawn airflow to the ground 74.

The semiconductor element testing system having an air filter, according to the present invention, can arrange appropriately the air filter on the top, or at one side, of the testing apparatus in compliance with actual structural requirement so as to produce an optimal dust-removal effect. Besides, the testing apparatus may be a wafer tester or a semiconductor handler.

In view of the above, the present invention may use the air filter to filter, with positive pressure, the air introduced into the testing apparatus, and into the testing area, so as to decrease floating particles in the testing area, and to maintain satisfactory cleanness in the testing area. This will lower the possibility of contamination to semiconductor elements, particularly CMOS elements which are easily contaminated, so as to enhance testing yield rate.

Although the present invention has been explained in relation to its preferred embodiments, it is to be understood that many other possible modifications and variations can be made without departing from the scope of the invention as hereinafter claimed.

What is claimed is:

1. A semiconductor element testing system having an air filter, comprising:
a testing apparatus, including a housing having an opening;
a first hollow frame, being flanged around the opening of the housing, and including a bottom surface and a side portion, wherein a plurality of hooks are fixedly arranged on the side portion;
a fan assembly, being fixed on the first hollow frame so as to provide a forced airflow toward inside of the housing;
a second hollow frame, including an inner bottom surface and an outer side portion, wherein the outer side portion is fixedly arranged with a plurality of loop fasteners corresponding to the plural hooks of the first hollow frame; and
an air filter, being interposed between the bottom surface of the first hollow frame and the inner bottom surface of the second hollow frame, and covering on the opening of the housing.

2. The semiconductor element testing system as claimed in claim 1, wherein the housing is provided, at its sides, with a plurality of slits acting as vents.

3. The semiconductor element testing system as claimed in claim 1, wherein the air filter relates to a high efficiency particulate air filter.

4. The semiconductor element testing system as claimed in claim 1, wherein the second hollow frame has a L-shaped cross-section.

5. The semiconductor element testing system as claimed in claim 1, wherein when the plural loop fasteners of the second hollow frame and the plural hooks of the first hollow frame are correspondingly engaged with one another, the air filter is pressed against by the bottom surface of the first hollow frame and the inner bottom surface of the second hollow frame.

6. The semiconductor element testing system as claimed in claim 1, wherein the fan assembly is fixed on the first hollow frame by a plurality of fastening screws.

7. The semiconductor element testing system as claimed in claim 1, wherein the first hollow frame, the fan assembly, the second hollow frame, and the air filter are assembled together so as to form a unitary fan-filter assembly which can be installed on the housing of the testing apparatus conveniently.

8. The semiconductor element testing system as claimed in claim 1, wherein the opening is provided at the top of the housing.

9. The semiconductor element testing system as claimed in claim 1, wherein the opening is provided at one side of the housing.

10. The semiconductor element testing system as claimed in claim 9, wherein a through hole is provided on the housing, opposite to the opening at the side of the housing.

11. The semiconductor element testing system as claimed in claim 10, wherein an exhaust fan is arranged at the through hole.

12. The semiconductor element testing system as claimed in claim 11, wherein the exhaust fan is provided with a shield.
